(19) United States
(12) Patent Application Publication
(10) Pub. No.: US 2014/0070289 A1
(43) Pub. Date: Mar. 13, 2014

(54) FERROELECTRIC MEMORY AND MANUFACTURING METHOD THEREOF

(71) Applicant: KABUSHIKI KAISHA TOSHIBA, Tokyo (JP)

(72) Inventors: Masayuki TANAKA, Yokkaichi-shi (JP); Junichi WADA, Yokkaichi-shi (JP); Yoshio OZAWA, Yokohama-shi (JP); Koji YAMAKAWA, Tokyo (JP); Seiji INUMIYA, Tokyo (JP); Atsuko SAKATA, Yokkaichi-shi (JP)

(21) Appl. No.: 14/016,771

(22) Filed: Sep. 3, 2013

(30) Foreign Application Priority Data
Sep. 10, 2012 (JP) 2012-198823

(51) Int. Cl. H01L 43/10

(52) U.S. Cl. CPC H01L 43/10
USPC 257/295

(57) ABSTRACT

According to one embodiment, a ferroelectric memory includes a gate insulation film formed on a semiconductor substrate, a ferroelectric film formed on the gate insulation film, and a control electrode formed on the ferroelectric film. The ferroelectric film is a film containing a metal, which is hafnium or zirconium, and oxygen, and contains an element other than the metal at a concentration lower than a concentration of the metal.

### CROSS-REFERENCE TO RELATED APPLICATIONS

This application is based upon and claims the benefit of priority from Japanese Patent Application No. 2012-198823, filed Sep. 10, 2012, the entire contents of which are incorporated herein by reference.

### FIELD

Embodiments described herein relate generally to a ferroelectric memory and a manufacturing method thereof.

### BACKGROUND

Attention has been paid to a ferroelectric memory as a nonvolatile memory which can operate at high speed. The ferroelectric memory is a memory which makes use of spontaneous polarization that is possessed by a ferroelectric body. There are a capacitor-type ferroelectric memory in which a transistor and a capacitor are combined, and a transistor-type ferroelectric memory which is used as a gate insulation film of a transistor.

In an example of the transistor-type ferroelectric memory, a ferroelectric phase of hafnium silicate (HfSiOx) is used. In this example, a gate insulation film is formed on a semiconductor substrate, an HfSiOx film, which is a ferroelectric film, is formed on this gate insulation film, and a control electrode is formed on this HfSiOx film. By using a voltage which is applied from the control electrode, polarization in the ferroelectric film is vertically inverted, thereby writing/erasing information in a memory cell. As regards this transistor-type ferroelectric memory, there has been a demand for enhancement of memory characteristics.

### BRIEF DESCRIPTION OF THE DRAWINGS

FIGS. 1A and 1B show one example of cross-sectional views in a channel length direction and in a channel width direction of a ferroelectric memory according to a first embodiment.

FIGS. 2A, 2B, 2C, 2D, and 2E show one example of a Si concentration distribution (1) which is non-uniform in a film thickness direction of a ferroelectric film in the first embodiment.

FIG. 3 is one example of a graph showing a relationship between a Si concentration and permittivity in an HfSiOx film in the first embodiment.

FIG. 4 is one example of a graph showing a relationship between a Si concentration and leak current in the HfSiOx film in the first embodiment.

FIGS. 5A and 5B show one example of a Si concentration distribution (2) which is non-uniform in the film thickness direction of the ferroelectric film in the first embodiment.

FIGS. 6A and 6B show one example of a Si concentration distribution (3) which is non-uniform in the film thickness direction of the ferroelectric film in the first embodiment.

FIGS. 7A, 7B, 7C, and 7D show one example of a Si concentration distribution (4) which is non-uniform in the film thickness direction of the ferroelectric film in the first embodiment.

FIGS. 8A, 8B, and 8C show one example of a Si concentration distribution (5) which is non-uniform in the film thickness direction of the ferroelectric film in the first embodiment.

FIGS. 9A, 9B, 9C, 9D, 9E, and 9F are one example of a cross-sectional view illustrating a manufacturing method of the ferroelectric memory according to the first embodiment.

FIGS. 10A and 10B show one example of cross-sectional views in a channel length direction and in a channel width direction of a ferroelectric memory according to a second embodiment.

FIGS. 11A, 11B, 11C, 11D, 11E, and 11F are one example of a cross-sectional view illustrating a manufacturing method of the ferroelectric memory according to the second embodiment.

FIG. 12 is one example of a graph showing insulation characteristics of a barrier multilayer structure for explaining an effect of the ferroelectric memory according to the second embodiment.

FIG. 13 is one example of a graph for describing Al concentration dependency of insulation characteristics for explaining the effect of the ferroelectric memory according to the second embodiment.

FIG. 14 is one example of a graph illustrating the dependency on heat treatment temperatures of a film thickness of a silicon substrate/silicon oxide film/alumina film in the second embodiment.

FIGS. 15A, 15B, and 15C show one example of cross-sectional views illustrating modifications of the ferroelectric memory according to the second embodiment.

FIG. 16 shows one example of cross-sectional views illustrating modifications of the ferroelectric memory according to the second embodiment.

FIGS. 17A, 17B, 17C, and 17D are one example of a cross-sectional view illustrating a manufacturing method of a ferroelectric memory according to a third embodiment.

FIGS. 18A, 18B, 18C, and 18D are one example of a cross-sectional view illustrating a manufacturing method of a ferroelectric memory according to a fourth embodiment.

FIGS. 19A, 19B, 19C, and 19D are one example of a cross-sectional view illustrating a manufacturing method of a ferroelectric memory according to a fifth embodiment.

FIGS. 20A, 20B, and 20C are one example of a cross-sectional view illustrating a manufacturing method of a ferroelectric memory according to a sixth embodiment.

### DETAILED DESCRIPTION

In general, according to one embodiment, a ferroelectric memory includes a gate insulation film formed on a semiconductor substrate, a ferroelectric film formed on the gate insulation film, and a control electrode formed on the ferroelectric film. The ferroelectric film is a film containing a metal, which is hafnium or zirconium, and oxygen, and contains an element other than the metal at a concentration lower than a concentration of the metal. The concentration of the element other than the metal is non-uniform in a film thickness direction of the ferroelectric film. The element other than the metal is silicon, magnesium, aluminum or yttrium. A concentration of the silicon, the magnesium, the aluminum or the yttrium is higher at an interface between the ferroelectric film and the gate insulation film and at an interface between the ferroelectric film and the control electrode than at a central part of the ferroelectric film. An atomicity of the element other than the metal/(the atomicity of the element other than the metal+an atomicity of the metal) is in a range of between 0.02 and 0.05 at the interface between the ferroelectric film and the gate insulation film.

Various embodiments will now be described with reference to the accompanying drawings. In the description, common parts throughout the drawings are denoted by common reference numerals.

### [1] First Embodiment

The inventors think that there are the following problems with a transistor-type ferroelectric memory in which a Si concentration distribution in an HfSiOx ferroelectric film is uniform in the film thickness direction.

(A) In order to promote higher integration/higher fineness, reduction in electrical film thickness of a cell insulation film (gate insulation film and ferroelectric film) is required.

(B) Side etching occurs at a part of an HfSiOx film in a chemical treatment process or a processing process in fabrication steps of the ferroelectric memory.

(C) In a thermal step in the manufacture of the ferroelectric memory, defects occur in the HfSiOx that is the ferroelectric film by the influence of a process atmosphere at a time of forming a control electrode, and defects form by mutual diffusion of constituent materials at an interface between the ferroelectric film and control electrode, the mutual diffusion resulting from a post-heating step.

This being the case, in the first embodiment, in a ferroelectric memory cell using an HfSiOx ferroelectric film, the distribution of the silicon concentration or nitrogen concentration in the film thickness direction is controlled, whereby the above items (A) to (C) are improved and a ferroelectric memory with excellent memory characteristics is realized.

[1-1] Structure

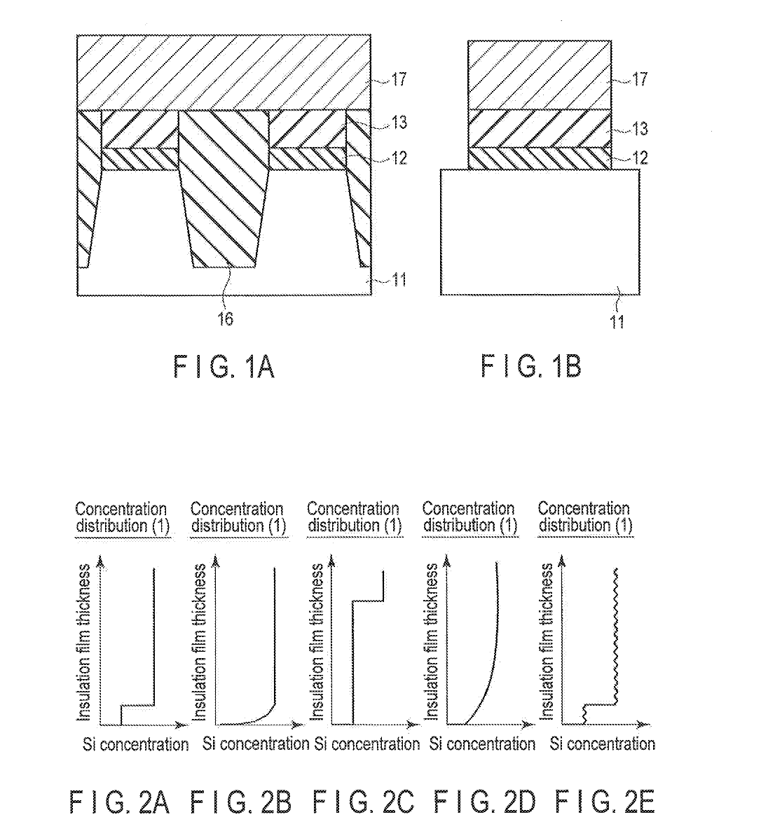

Referring to FIGS. 1A and 1B, the structure of a ferroelectric memory according to the first embodiment is described. FIG. 1A is a cross-sectional view in a word line direction (channel width direction), and FIG. 1B is a cross-sectional view in a bit line direction (channel length direction).

As shown in FIGS. 1A and 1B, device regions, in which a plurality of memory cells are formed, are isolated by device isolation insulation films 16. The plural device isolation insulation films 16, which extend in parallel to each other, are formed between a silicon substrate (semiconductor substrate) 11 and a plurality of memory cell columns. A gate insulation film 12 is formed on the silicon substrate 11, a ferroelectric film 13 is formed on the gate insulation film 12, and a control electrode 17 is formed on the ferroelectric film 13.

The ferroelectric film 13 is a film containing as main constituents a metal (e.g. hafnium (Hf), zirconium (Zr)) and oxygen, and contains an element (e.g. silicon (Si), magnesium (Mg), aluminum (Al), yttrium (Y)) other than the metal at a concentration lower than a concentration of the metal. The ferroelectric film 13 is formed of, for example, an HfSiOx film, a ZrSiOx film, an HfMOx film, a ZrMgOx film, etc.

In the case where the ferroelectric film 13 is the HfSiOx film, it is preferable that the Si concentration in the HfSiOx film be in a range of between 002 and 0.05, if the ferroelectric film 13 is to have ferroelectricity. A higher ferroelectricity can be obtained if the Si concentration in the HfSiOx film is in a range of between 0.026 and 0.034. Incidentally, the definition of the Si concentration in the HfSiOx film is Si atomicity/(Si atomicity Hf atomicity). In the description below, the concentration of the element (Si, Mg, Al or Y) other than the metal (Hf or Zr), which is the main constituent in the ferroelectric film 13, means the Si, Mg, Al or Y atomicity/(Si, Mg, Al or Y atomicity+Hf or Zr atomicity).

In this present embodiment, the concentration of the element (Si, Mg, Al or Y) other than the metal (Hf or Zr), which is the main constituent in the ferroelectric film 13, is non-uniform in the film thickness direction. The details will be described later.

[1-2] Concentration Distribution (1)

The concentration distribution (1) in the present embodiment indicates the Si concentration in the film thickness direction in the HfSiOx film that is the ferroelectric film 13. This concentration distribution (1) is effective in improving the above item (A), and will now be described with reference to FIGS. 2A, 2B, 2C, 2D, and 2E. As regards the ordinate in the Figure, the lower side is the gate insulation film 12 side, and the upper side is the control electrode 17 side.

As shown in FIGS. 2A, 2B, 2C, 2D, and 2E, in the concentration distribution (1), the interface between the gate insulation film 12 and ferroelectric film 13 has such an Si concentration as to have necessary ferroelectricity as the ferroelectric memory. The other part has such a Si concentration as to have a high permittivity and a higher dielectric breakdown strength. In the concentration distribution (1), the Si concentration in the ferroelectric film 13 is higher on the control electrode 17 side than on the gate insulation film 12 side, and has a non-uniform distribution in the film thickness direction.

Specifically, the Si concentration on the gate insulation film 12 side of the ferroelectric film 13 is, for example, in a range of between 0.02 and 0.05, preferably in a range of between 0.026 and 0.034. On the other hand, the Si concentration on the control electrode 17 side of the ferroelectric film 13 is, for example, in a range of between 0.05 and 0.2, preferably in a range of between 0.05 and 0.1, and more preferably about 0.05.

In the case of FIG. 2A, the ferroelectric film 13 has a two-step concentration distribution of a low-concentration region and a high-concentration region. The low-concentration region of the ferroelectric film 13 is near the interface between the gate insulation film 12 and the ferroelectric film 13, and the Si concentration is constant at a low value (e.g. Si concentration=0.026 or more and 0.034 or less). The high-concentration region of the ferroelectric film 13 is a region other than the vicinity of the interface between the gate insulation film 12 and ferroelectric film 13, and the Si concentration is constant at a high value (e.g. Si concentration=0.05 or more and 0.1 or less).

In the case of FIG. 2B, the ferroelectric film 13 has a Si concentration which gradually increases from the interface between the gate insulation film 12 and ferroelectric film 13 toward the control electrode 17 (e.g. Si concentration=0.026 or more and 0.034 or less), and then the Si concentration is kept constant (e.g. Si concentration=0.05 or more and 0.1 or less).

In the case of FIGS. 2C and 2D, compared to the case of FIGS. 2A and 2B, the low-concentration region of Si in the ferroelectric film 13 becomes wider. In this manner, the low-concentration region of Si is not limited to the interface between the gate insulation film 12 and ferroelectric film 13.

FIGS. 2A, 2B, 2C, and 2D, the Si concentration in the ferroelectric film 13 is distributed in a straight line or a curve in the film thickness direction. Alternatively, as shown FIG. 2E, the Si concentration may be distributed in a wavy line with variation. This concentration distribution can be examined by SIMS.

As has been described above, according to the concentration distribution (1), on the side of the interface with the gate insulation film 12, a ferroelectric film with such a Si concentration as to have ferroelectricity as the ferroelectric memory is formed. At the other part, a hafnium silicate layer having a high permittivity and a high dielectric breakdown strength and having, a higher Si concentration than the ferroelectric layer is formed. Thereby, the above item (A) can be improved, as will be described below.

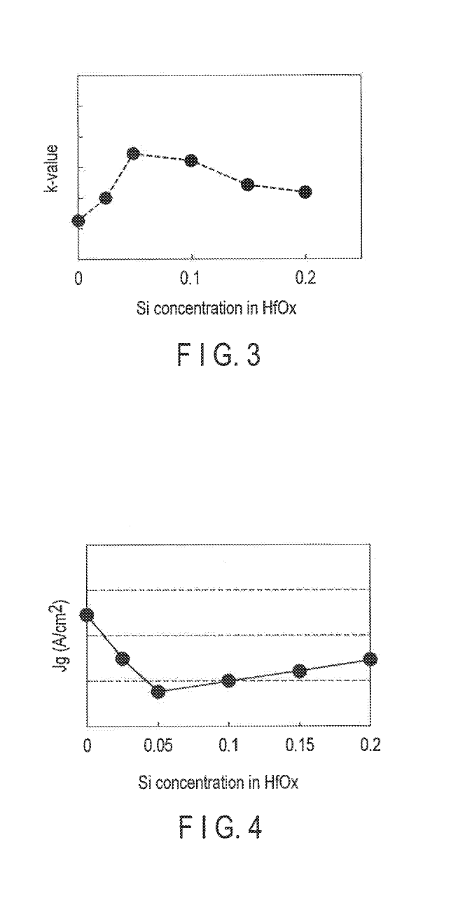

To begin with, referring to FIG. 3, the Si concentration dependency of the permittivity (k-value) of the HfSiOx film is described. The permittivity is calculated from an electrical film thickness and a physical film thickness which are obtained from a MIS capacitor. As shown in FIG. 3, the permittivity takes a maximum value when the Si concentration is 0.05˜0.1. This maximum permittivity can be increased by about 20%, compared to a permittivity in a case where the Si concentration is about 0.02 to 0.03. Specifically, the permittivity on the control electrode 17 side of the ferroelectric electrode 13 can be increased by setting the Si concentration distribution on the control electrode 17 side in the ferroelectric film 13 in range of about 0.05˜0.1, as in the concentration distribution (1) of the present embodiment. Thus, the electrical film thickness of the cell insulation film can be reduced.

Next, referring to FIG. 4, the Si concentration dependency of leak current (Jg) of the HfSiOx film is described. In FIG. 4, the ordinate indicates leak current density at a time of application of high electric field, which is calculated from the MIS capacitor. As shown in FIG. 4, by doping Si in an HfOx film, the leak current is decreased. Specifically, the leak current can be decreased by about an order of magnitude when the Si concentration is about 0002˜0.03, and by about 1.5 to 2 orders of magnitude when the Si concentration is about 0.05 to 0.1. Thus, by forming the concentration distribution (1) of the present embodiment, the leak current of the cell insulation film can be reduced.

[1-3] Concentration Distribution (2)

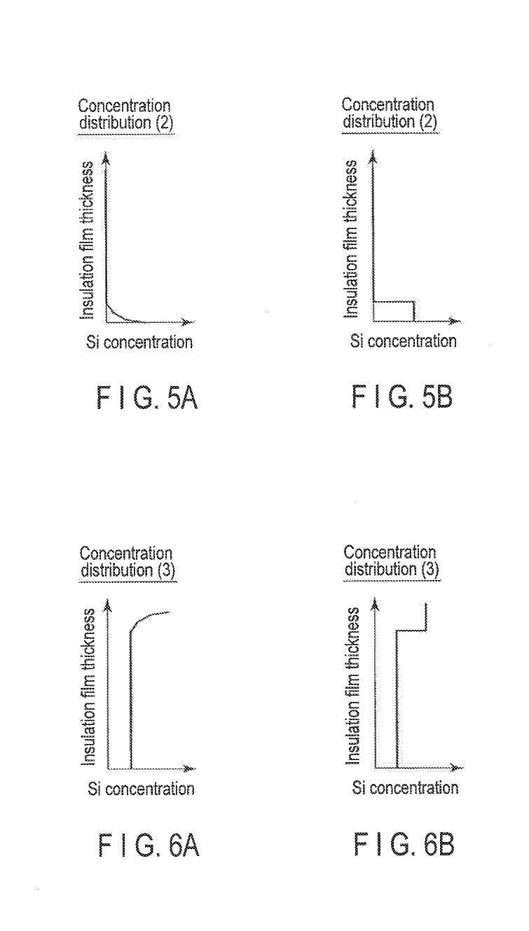

A concentration distribution (2) of the present embodiment is indicative of a Si concentration in the film thickness direction in the HfSiOx film that is the ferroelectric film 13. This concentration distribution (2) is effective in solving the above problem (B), and will now be described with reference to FIGS. 5A and 5B.

As shown in FIGS. 5A and 5B, in the concentration distribution (1), a Si concentration with ferroelectricity is provided at only the vicinity of the interface between the gate insulation film 12 and ferroelectric film 13. At the other part, for example, an HfOx film without doping of Si is formed.

In the case of FIG. 5A, the Si concentration at the interface between the gate insulation film 12 and ferroelectric film 13 takes a maximum value in the vicinity of the interface between the gate insulation film 12, which is doped with Si, and the ferroelectric film 13, and the Si concentration gradually decreases. In this case, the Si concentration is, for example, in a range of between 0.026 and 0.034.

In the case of FIG. 5B, the Si concentration is kept substantially constant in the vicinity of the interface between the gate insulation film 12, which is doped with Si, and the ferroelectric film 13. In this case, the Si concentration is, for example, in a range of between 0.026 and 0.034.

As described above, according to the concentration distribution (2), by doping Si in the HfOx near the interface between the gate insulation film 12 and the ferroelectric film 13, the resistance to chemical solution decreases and the amount of etching by chemical solution increases. It appears that this is partly because the temperature of crystallization rises by doping of Si, and an increase in density becomes difficult to occur. Thereby, side-etching of a bulk part due to chemical solution treatment can be suppressed.

[1-4] Concentration Distribution (3)

A concentration distribution (3) of the present embodiment is indicative of a Si concentration in the film thickness direction in the HfSiOx film that is the ferroelectric film 13. This concentration distribution (3) is effective in improving the above item (C), and will now be described with reference to FIGS. 6A and 6B.

In a metal oxide formed by using Hf as a metal element, the electrode interface between the ferroelectric film 13 and control electrode 17 deteriorates by the influence of a process atmosphere or a post-heating step at a time of forming the control electrode 17. As regards the atmosphere at the time of forming the control electrode 17, for example, in the case of a silicon electrode, oxygen deficiency of the ferroelectric film 13, for instance, occurs due to a reducing atmosphere of silane, etc. in the case of a silicon electrode, or an etching effect of a metal chloride gas in the case of a metal nitride electrode of tungsten nitride, etc. In addition, owing to a high-temperature film formation process after formation of an electrode interface, or heat treatment for activation, film characteristics deteriorate by mutual diffusion of a metal element, nitrogen, etc. at the electrode interface, or absorption of oxygen. The tendency of degradation at the electrode interface is greater as the Hf concentration is higher.

Thus, in the concentration distribution (3), as shown in FIGS. 6A and 6B, at the interface between the control electrode 17 and ferroelectric film 13, the Hf concentration in the ferroelectric film 13 is decreased and the Si concentration is increased. As regards the HfSiOx film which is formed at the electrode interface, there may be a case in which Si=100% at maximum, that is, a silicon oxide film is formed. In the meantime, as the thickness of the silicon oxide film is greater, the degradation suppressing effect is greater, but the electrical film thickness becomes larger. It is preferable to determining the film thickness by optimizing both the degradation suppressing effect and the electrical film thickness.

In the case of FIG. 6A, Si with a fixed concentration (e.g. in a range of between 0.026 and 0.034) is doped from the interface between the gate insulation film 12 and ferroelectric film 13 toward the control electrode 17, and the Si concentration gradually increases in the vicinity of the interface between the control electrode 17 and ferroelectric film 13.

In the case of FIG. 6B, Si with a fixed high concentration is doped in the vicinity of the interface between the control electrode 17 and ferroelectric film 13.

As has been described above, according to the concentration distribution (3), the Si concentration is increased at the interface between the control electrode 17 and ferroelectric film 13. Thereby, since oxygen deficiency at the electrode interface can be suppressed, the degradation of the electrode interface can be suppressed.

[1-5] Concentration Distribution (4)

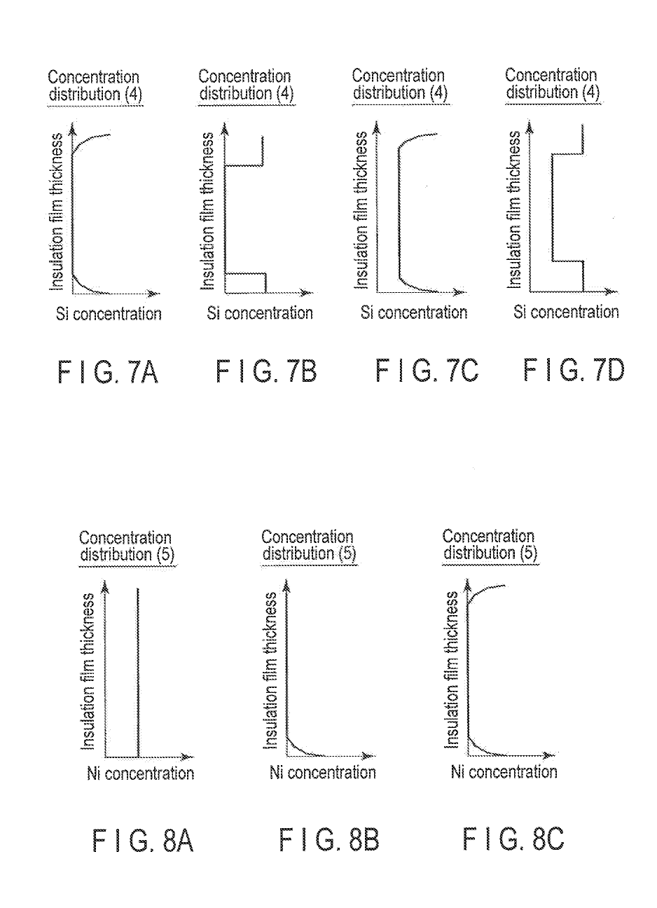

Referring to FIGS. 7A, 7B, 7C, and 7D, examples of combinations of the concentration distributions (1) to (3) are described. In the meantime, in the present embodiment, combinations of the concentration distributions (1) to (3), which are not shown in FIGS. 7A, 7B, 7C, and 7D, are possible as a matter of course.

As shown in FIGS. 7A and 7B, it is possible to adopt such a Si distribution that Si is doped at both the interface between the gate insulation film 12 and ferroelectric film 13 and the interface between the control electrode 17 and ferroelectric film 13, and no Si is doped in the central part other than these interfaces. Specifically, the Si concentration at the interface between the gate insulation film 12 and ferroelectric film 13 and the interface between the control electrode 17 and ferroelectric film 13 is higher than the Si concentration in the central part of the ferroelectric film 13.

As shown in FIGS. 7C and 7D, Si may be doped at both the interface between the gate insulation film 12 and ferroelectric film 13 and the interface between the control electrode 17 and ferroelectric film 13, and Si with a fixed concentration may be doped in the central part other than these interfaces.

[1-6] Concentration Distribution (5)

A concentration distribution (5) of the present embodiment is described with reference to FIGS. 8A, 8B, and 8C.

As shown in FIGS. 8A, 8B, and 8C, in the concentration distribution (5), defects in the ferroelectric film 13 and at the interface of the ferroelectric film 13 are reduced by introducing nitrogen (N) in the HfSiOx film.

In the case of FIG. 8A, nitrogen is introduced at a fixed concentration in the film thickness direction of the HfSiOx film. In this case, the nitrogen concentration is, for example, in a range of between 0.1 atoms/cm² and 10 atoms/cm². Incidentally, “atoms/cm²” may be replaced with “atomic/cm²”. In this manner, by introducing nitrogen in the ferroelectric film 13, the dielectric breakdown strength of the HfSiOx film can be improved, and leak current of the cell insulation film can be reduced.

In the case of FIG. 8B, nitrogen is introduced in only the vicinity of the interface between the gate insulation film 12 and ferroelectric film 13. In this manner, by restricting the part of formation of nitrogen to the vicinity of the electrode interface, the device characteristics can be improved. In short, since a high ferroelectricity of the bulk part is obtained, the film thickness of the cell insulation film can be reduced.

In the case of FIG. 8C, nitrogen is introduced at both the interface between the gate insulation film 12 and ferroelectric film 13 and the interface between the control electrode 17 and ferroelectric film 13. In this manner, also by restricting the part of formation of nitrogen to both the electrode interface and the vicinity of the gate insulation film, the device characteristics can be improved. In short, since a high ferroelectricity of the bulk part is obtained, the film thickness of the cell insulation film can be reduced. In addition, it is possible to suppress degradation of the HfSiOx film due to the effect of a process atmosphere at a time of electrode formation, or degradation at the HfSiOx film/electrode interface in a post-heating step.

As has been described above, according to the concentration distribution (5), the device characteristics can be improved, as described above, by uniformly or non-uniformly introducing nitrogen in the ferroelectric film 13 in the film thickness direction.

In the meantime, the concentration distribution (5) may be a distribution as illustrated in the concentration distributions (1) to (4). Furthermore, as regards the Si or N concentration distributions, not only with the above-illustrated concentration distributions (1) to (5), but also with various combinations of these distributions or with modified distributions, the advantageous effects of the present embodiment can be obtained. Besides, both Si and N may be introduced in the ferroelectric film 13. In the ferroelectric film 13, Mg, Al or Y, instead of Si, having the above-described concentration distributions (1) to (4), may be introduced.

[1-7] Manufacturing Method

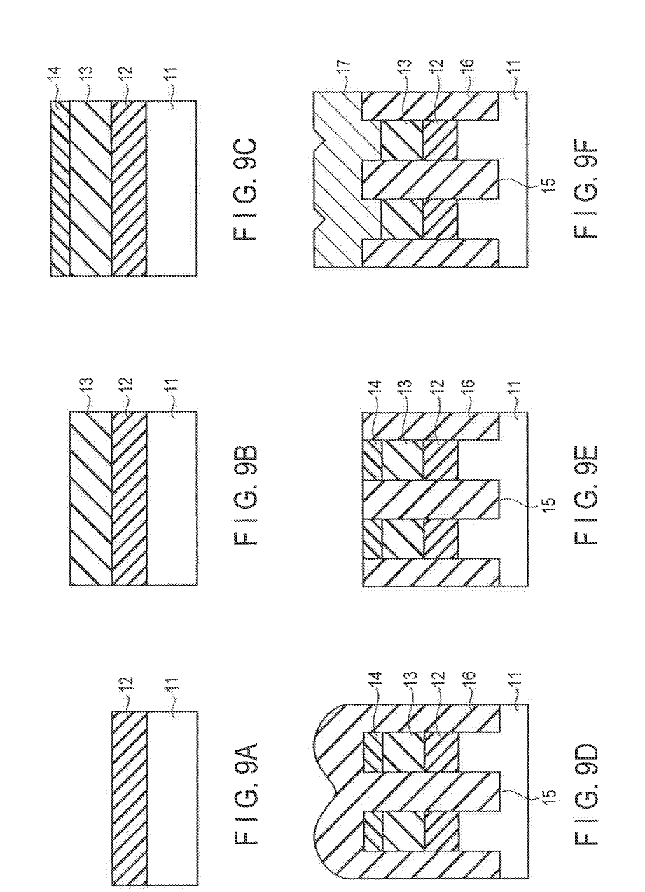

Referring to FIGS. 9A, 9B, 9C, 9D, 9E, and 9F, a description is given of a manufacturing method of the ferroelectric memory according to the first embodiment.

To start with, as shown in FIG. 9A, a silicon oxide film with a film thickness of 1 nm to 10 nm is formed as a gate insulation film 12 on a p-type silicon substrate (or a p-type well formed on an n-type silicon substrate).

Next, as shown in FIG. 9B, an HfSiOx film, which is a ferroelectric film 13, is formed on the gate insulation film 12 by an atomic layer deposition (ALD) method. The film thickness of the HfSiOx film is in a range of between 5 nm and 20 nm. Where necessary, heat treatment such as densification or oxidation may be performed. The hafnium silicate film is formed by an ALD method. The silicon source is trisdimethyl amino silane (TrisDMAS), and the hafnium source is tetrakis ethylmethyl amino hafnium (TEMAH). The Si concentration in the HfSiOx film is controlled by a cycle number of ALD so as to become a desired concentration. Ozone is used as an oxidizer, and film formation is performed at 300° C. In this ALD method, film formation is performed in units of an atomic layer, by repeating a plurality of number of times a sequence of supply of active gas such as ozone, purge by vacuum evacuation, supply of material gas such as TEMAH or TrisDMAS, purge by vacuum evacuation, and re-supply of active gas such as ozone.

In the meantime, as the method of forming the hafnium silicate film in the embodiment, methods other than the above method may be used. For example, the source of hafnium or silicon may be other materials, such as alkyl amino hafnium or hafnium halide, in which a component other than an ethylmethyl amino group is coupled to the hafnium element. The oxidizer May be other material such as water, oxygen, oxygen radicals, etc. In addition, the film formation method is not limited to the ALD method, and use may be made of, for example, chemical vapor deposition (CVD), physical vapor deposition (PVD) using physical excitation, a coating method, etc.

Next, as shown in FIG. 9C, using a conventional method, a silicon oxide film and a silicon nitride film, which become a hard mask 14, are formed on the ferroelectric film 13. The total film thickness of the silicon oxide film and silicon nitride film is, for example, 50 to 150 nm.

Next, as shown in FIG. 9D, a photoresist (not shown) is coated, and the resist is patterned by exposure drawing. Using this photoresist (not shown) as an etching-resistant mask, the silicon oxide film is etched. After the etching, the photoresist is removed. Then, using the silicon oxide film as a mask, the silicon nitride mask is etched, and subsequently the ferroelectric film 13, gate insulation film 12 and silicon substrate 11 are etched. Thereby, a device isolation trench 15 for device isolation is formed. Following this, by a coating technique, a device isolation insulation film 16 with a thickness of 200 nm to 1500 nm is formed and buried in the device isolation trench 15. The density of the device isolation insulation film 16 is increased by treatment in an oxygen atmosphere or a water vapor atmosphere.

Next, as shown in FIG. 9E, using the silicon nitride film of the hard mask 14 as a stopper, the device isolation insulation film 16 is planarized by chemical mechanical polishing (CMP). Then, only the device isolation insulation film 16 is etched back under an etching condition with selectivity to the silicon nitride film.

Subsequently, as shown in FIG. 9F, a control gate (CG) 17 is formed on the ferroelectric film 13 and device isolation insulation film 16. This control electrode 17 is formed of titanium nitride, tantalum nitride, tungsten nitride, impurity-doped silicon, etc. Then, after the control electrode 17 is patterned by exposure drawing, the ferroelectric memory is completed through an ordinary post-step.

In the above-described manufacturing method of the ferroelectric memory of the embodiment, in the step of FIG. 9B, for example, the above-described concentration distributions (1) to (5) are formed in the manner as described below.

In the concentration distribution (1) shown in FIG. 2A, for example, the film thickness of the HfSiOx film is 10 nm, and the number of cycles in the ALD method is 110. In this case, the adsorption amount of Hf for one cycle is 4e14 cm⁻², and the adsorption amount of Si is 1e14 cm⁻². The cycle number ratio of the initial 10 cycles is Hf:Si=9:1. The Si concentration corresponds to 0.027. The position of insertion, of Si is approximately at the center. The cycle number ratio of the latter 100 cycles is Hf:Si 7:3, and the Si concentration corresponds to 0.097. The position of insertion of Si is such a position that Si is formed in 1 cycle, for example, for Hf 2 cycles. At last, Hf is formed in 1 cycle.

In the concentration distribution (1) shown in FIG. 2B, the HfSiOx film is formed by CVD. At this time, the flow rate of Si is increased five times for a film thickness of about 1 nm.

When the concentration distributions (5) shown in FIGS. 8A, 8B, and 8C are formed, the introduction of nitrogen in the HfSiOx film is carried out in the following manner. In the case of FIG. 8A, the uniform nitrogen introduction in the film thickness direction is carried out by performing radical nitriding in every ALD cycle. In the case of FIG. 8B, the introduction of nitrogen at the interface of the gate insulation film 12/ferroelectric film 13 is carried out by performing nitrogen monoxide (NO) anneal after the formation of HfSiOx. The NO anneal temperature is in a range of between 500° C. and 1000° C. In the case of FIG. 8C, the introduction of nitrogen at the interface of the gate insulation film 12/ferroelectric film 13 and the interface of the control electrode 17/ferroelectric film 13 is carried out by anneal with ammonia after the formation of HfSiOx. The anneal temperature is in a range of between 500° C. and 1000° C. Incidentally, the introduction of nitrogen at the interface of the control electrode 17/ferroelectric film 13 may be performed by radial nitriding.

[1-8] Advantageous Effects

According to the above-described first embodiment, in the film thickness direction of the ferroelectric film 13, the concentration distribution of silicon or nitrogen is controlled. Thereby, it becomes possible to achieve reduction in leak current, reduction in thickness of the cell insulation film, suppression of side etching of the ferroelectric film 13, and suppression of degradation at the interface of the control electrode 17/ferroelectric film 13. Therefore, the cell characteristics of the ferroelectric memory can be improved, and higher capabilities can be realized.

### [2] Second Embodiment

In a second embodiment, in a ferroelectric memory using an HfSiOx ferroelectric film, a barrier film (e.g. aluminum oxide, silicon nitride film) is formed at an interface between a silicon oxide film, which is a gate insulation film, and a ferroelectric film, thereby achieving (i) reduction in leak current and (ii) suppression of degradation of ferroelectricity occurring at the interface between the silicon oxide film and ferroelectric film, and realizing a ferroelectric memory with excellent memory characteristics.

[2-1] Structure

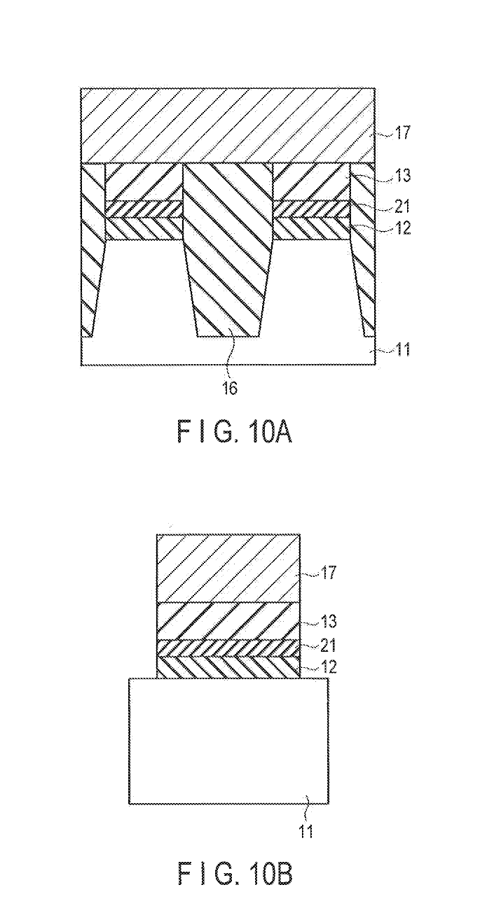

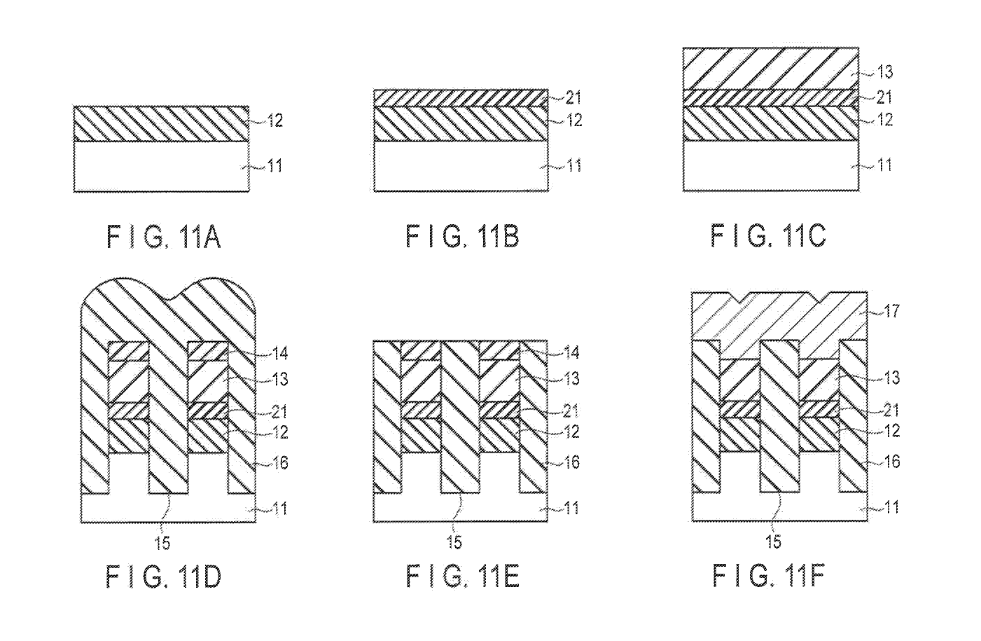

Referring to FIGS. 10A and 10B, the structure of a ferroelectric memory according to the second embodiment is described. FIG. 10A is a cross-sectional view in the word line direction (channel width direction), and FIG. 10B is a cross-sectional view in the bit line direction (channel length direction).

As shown in FIGS. 10A and 10C, device regions, in which a plurality of memory cells are formed, are isolated by device isolation insulation films 16. The plural device isolation insulation films 16, which extend in parallel to each other, are formed between a silicon substrate 11 and a plurality of memory cell columns. A gate insulation film 12 is formed on the silicon substrate 11, a ferroelectric film 13 is formed on the gate insulation film 12, and a control electrode 17 is formed on the ferroelectric film 13.

In the second embodiment, a barrier film 21, which is formed of, e.g. alumina (Al₂O₃), is formed at the interface between the gate insulation film 12 and ferroelectric film 13.

The barrier film 21 is, for example, an aluminum-containing film. The aluminum-containing film may be formed of any material containing aluminum, such as an aluminum metal, aluminum oxide, aluminum nitride, aluminum carbide, aluminum boride, or aluminum sulfide. In addition, the metal concentration of aluminum in the aluminum-containing film should preferably be 1e12 atoms/cm² or more (see FIG. 13). The film thickness of the aluminum-containing film should preferably be 0.001 nm or more in terms of single-crystal sapphire.

The barrier film 21 is not limited to aluminum, and may be a non-transition metal element such as beryllium (Be), magnesium (Ma), strontium (Sr) or barium (Ba), boron (B), a compound thereof, an oxide thereof, a nitride thereof, a boride thereof, a sulfide thereof, a semimetal, a transition metal element such as lanthanum, or a compound thereof.

From the oxygen retention density in a single-crystal state, it is assumed that an element with a smaller atomic number forms a greater electric dipole. Thus, in order to enhance the leak resistance of the insulation film, it is preferable to use an element with a smaller atomic number.

Boron is also effective in forming a greater electric dipole, since boron has a smaller atomic weight than aluminum and increases oxygen density. In the case of boron, however, diffusion into the silicon oxide film tends to occur more easily. Thus, when a silicon oxide film is formed on the barrier layer 21, it is desirable to create a state with a higher oxygen density than the silicon oxide film, on the uppermost layer of layers including the above-described elements.

In the case of the non-transition element, oxygen deficiency hardly occurs, and thus the non-transition element is a more desirable element in order to decrease high electric field leak. On the other hand, the transition metal tends to easily stabilize oxygen deficiency, and thus the transition metal can bring about effects by optimizing process conditions. For example, a film containing lanthanum may be formed as the barrier film 21 at the interface between the silicon oxide film (gate insulation film 12) and HfSiOx film (ferroelectric film 13).

The ferroelectric film 13 is a film containing as main constituents a metal (e.g. hafnium (Hf), zirconium (Zr)) and oxygen, and contains an element (e.g. silicon (Si), magnesium (Mg), aluminum (Al), yttrium (Y)) other than the metal at a concentration lower than the concentration of the metal. The ferroelectric film 13 is formed of, for example, an HfSiOx film, a ZrSiOx film, an MfMgOx film, a ZrMgOx film, etc.

In the case where the ferroelectric film 13 is the HfSiOx film, it is desirable that the Si concentration in the HfSiOx film be in a range of between 0.02 and 0.05, if the ferroelectric film 13 is to have ferroelectricity. A higher ferroelectricity can be obtained if the Si concentration in the HfSiOx film is in a range of between 0.026 and 0.034.

[2-2] Manufacturing Method

Referring to FIGS. 11A, 11B, 11C, 11D, 11E, and 11F, a description is given of a manufacturing method of the ferroelectric memory according to the second embodiment.

To start with, as shown in FIG. 11A, a silicon oxide film with a film thickness of 1 nm to 10 nm is formed as a gate insulation film 12 on a p-type silicon substrate (or a p-type well formed on an n-type silicon substrate).

Next, as shown in FIG. 11B, an aluminum-containing film is formed as a barrier film 21. In this example, an aluminum oxide film (alumina film) is formed as the aluminum-containing film. The metal concentration of aluminum is in a range of between 1e12 atoms/cm² and 1e16 atoms/cm². The film thickness of the aluminum oxide film is about 0.001 nm to 1 nm.

The aluminum oxide film is formed by an ALD method. To be more specific, trimethyl aluminum (TMA) is used as an aluminum source, ozone is used as an oxidizer, and the film-formation temperature is 300° C. In this ALD method, film formation is performed in units of an atomic layer, by repeating a plurality of number of times a sequence of supply of active gas such as ozone, purge by vacuum evacuation, supply of metal material gas such as TMA, purge by vacuum evacuation, and re-supply of active gas such as ozone.

In the meantime, as the method of forming the aluminum oxide film in the embodiment, various methods other than the above method may be used. For example, the aluminum-containing film may be formed by having an aluminum-containing gas or liquid adsorbed on an underlayer surface, or may be formed of molecules including aluminum and carbon or nitrogen. The source of aluminum may be other alkyl aluminum in which an alkyl group, other than a methyl group, is coupled to an aluminum element, an amino-based material in which an amino group is coupled to an aluminum element, or aluminum halide. The oxidizer may be other material such as water, oxygen, oxygen radicals, etc. In addition, the film formation method is not limited to the ALD method, and use may be made of, for example, chemical vapor deposition (CVD), physical vapor deposition (PVD) using physical excitation, a coating method, or a method of immersion and adsorption in a solution in which the corresponding ions are dissolved. Besides, the oxidizer is not limited to ozone. Other oxidizers, such as oxygen, water, oxygen radicals, or nitrogen suboxide, are similarly effective.

Next, as shown in FIG. 11C, an HfSiOx film, which is a ferroelectric film 13, is formed on the gate insulation film 12 by an atomic layer deposition (ALD) method. The film thickness of the HfSiOx film is in a range of between 5 nm and 20 nm. Where necessary, heat treatment, such as densification or oxidation, may be performed. The hafnium silicate film is formed by an ALD method. The silicon source is trisdimethyl amino silane (TrisDMAS), and the hafnium source is tetrakis ethylmethyl amino hafnium (TEMAH). The Si concentration in the HfSiOx film is controlled by a cycle number of ALD so as to become 0.02 to 0.05. Ozone is used as an oxidizer, and film formation is performed at 300° C. In this ALD method, film formation is performed in units of an atomic layer, by repeating a plurality of number of times a sequence of supply of active gas such as ozone, purge by vacuum evacuation, supply of material gas such as TEMAH or TrisDMAS, purge by vacuum evacuation, and re-supply of active gas such as ozone.

Next, as shown in FIG. 11D, using a conventional method, a silicon oxide film and a silicon nitride film, which become a hard mask 14, are formed on the ferroelectric film 13. The total film thickness of the silicon oxide film and silicon nitride film is, for example, 50 to 150 nm.

Next, a photoresist (not shown) is coated, and the resist is patterned by exposure drawing. Using this photoresist (not shown) as an etching-resistant mask, the silicon oxide film is etched. After the etching, the photoresist is removed. Then, using the silicon oxide film as a mask, the silicon nitride mask is etched, and subsequently the ferroelectric film 13, gate insulation film 12 and silicon substrate 11 are etched. Thereby, a device isolation trench 15 for device isolation is formed. Following this, by a coating technique, a device isolation insulation film 16 with a thickness of 200 nm to 1500 nm is formed and buried in the device isolation trench 15. The density of the device isolation insulation film 16 is increased by treatment in an oxygen atmosphere or a water vapor atmosphere.

Next, as shown in FIG. 11E, using the silicon nitride film of the hard mask 14 as a stopper, the device isolation insulation film 16 is planarized by CMP. Then, only the device isolation insulation film 16 is etched back under an etching condition with selectivity to the silicon nitride film.

Subsequently, as shown in FIG. 11F, a control gate (CG) 17 is formed on the ferroelectric film 13 and device isolation insulation film 16. Then, after the control electrode 17 is patterned by exposure drawing, the ferroelectric memory is completed through an ordinary post-step.

[2-3] Advantageous Effects

According to the above-described second embodiment, the barrier film 21 is formed at the interface between the gate insulation film (e.g. silicon oxide film) 12 and the ferroelectric film (e.g. HfSiOx film) 13. Thereby, it is possible to achieve (i) reduction in leak current and (ii) suppression of degradation of ferroelectricity occurring at the interface between the gate insulation film 12 and ferroelectric film 13. Therefore, the cell characteristics of the ferroelectric memory can be improved, and higher capabilities can be realized. The details will be described below. In the description below, the barrier film 21 is exemplified by an aluminum-containing film, but the same advantageous effects can be obtained with barrier films other than the above-described aluminum-containing film.

[2-3-1] Reduction in Leak Current

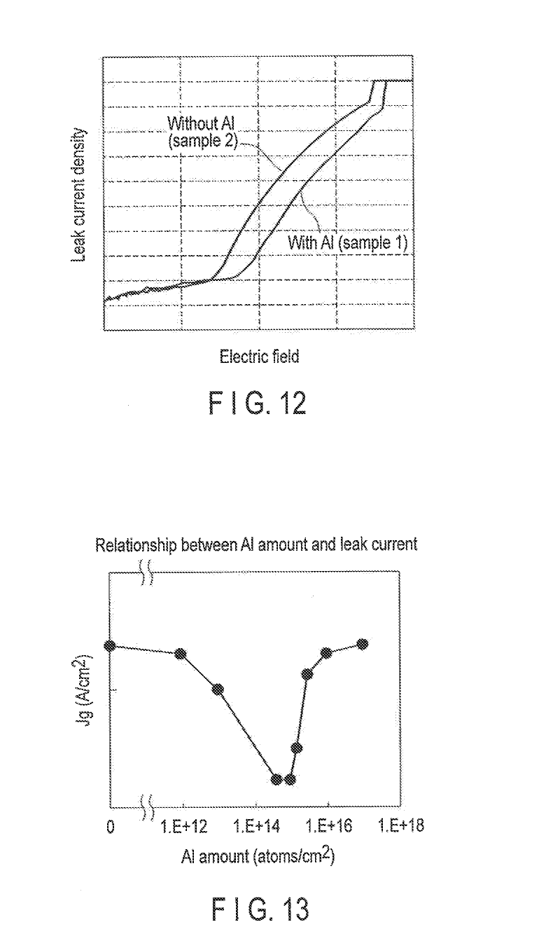

Referring to FIG. 12 and FIG. 13, reduction in leak current is explained.

FIG. 12 shows insulation characteristics of samples 1 and 2, that is, the relationship between an electric field and leak current density. In sample 1, an aluminum-containing film is formed at an interface between a silicon nitride film and a silicon oxide film. In sample 2, an aluminum-containing film as in sample 1 is not formed, and a silicon oxide film is formed on a silicon nitride film.

As shown in FIG. 12, it is understood that by forming the aluminum-containing film at the silicon oxide film/silicon nitride film interface, as in sample 1, the leak current density decreases in almost the entire electric field region, compared to sample 2. This result indicates that the energy band structure varied by forming the aluminum-containing film at the silicon oxide film/silicon nitride film interface. Specifically, by forming the barrier film 21, which is formed of the aluminum-containing film, at the interface between the gate insulation film 12 and ferroelectric film 13, as in the present embodiment, the energy band structure at the interface varies, and thus the leak current can be suppressed.

FIG. 13 shows a relationship between Al concentration and leak current density. In a sample used in this example, a silicon nitride film is formed on a silicon substrate, an aluminum oxide film with a desired Al concentration is formed on this silicon nitride film, and a silicon oxide film is formed on the aluminum oxide film. The result of FIG. 13 is obtained by MIS capacitor evaluation, and a sample, in which electrons are injected from the silicon substrate side and the aluminum oxide is not formed, is used as a reference.

As shown in FIG. 13, an improvement of insulation characteristics depends on the Al concentration (Al density, Al surface density). Specifically, the effect of leak current reduction varies depending on the Al concentration. For example, when the Al concentration is in a range of between 1e12 atoms/cm² and 1e16 atoms/cm², the effect of leak current reduction is high, compared to the reference. Particularly effective is when the AL concentration is in the neighborhood of 1e14 atoms/cm². These indicate that there is an optimal concentration when dipole effects are exhibited.

As a reason why the effect of leak current reduction is exhibited in the aluminum oxide, the following model is considered

When a silicon oxide film is formed on top of an aluminum metal or compound, an uppermost layer of the aluminum-containing film is oxidized, and aluminum oxide is formed. The silicon oxide film and aluminum oxide have different oxygen densities, and the aluminum oxide has a higher oxygen density. Accordingly, it can be considered that oxygen ions of the aluminum oxide shifted to the silicon oxide film side at the interface between the silicon oxide film and the aluminum oxide. It is considered that an electric dipole was formed at the interface by the shift of oxygen ions, and thereby such a band modulation occurred that the electron barrier of the silicon oxide film becomes higher.

In the meantime, as a reason why the effect is exhibited by an element other than the aluminum oxide constituting the aluminum-containing film, it is considered that the aluminum compound of the surface layer of the aluminum-containing film is oxidized and thereby the above-described effect was exhibited.

The following advantageous effect is obtained, depending on the kind of aluminum compound which is formed at the interface between the silicon oxide film and the aluminum-containing film. When aluminum oxide is formed, impurities due to the source at the time of aluminum formation or impurities adsorbed on the surface can be effectively removed by an oxidizer. Thus, an excellent interface can be formed. In addition, when aluminum nitride is formed, diffusion of silicon can be suppressed. When aluminum boride is formed, since an oxide itself of boron is an element which contributes to a dipole effect, a higher dipole effect can be obtained. Moreover, when aluminum sulfide is formed, since aluminum can be formed at low density, an aluminum layer with a lower concentration can easily be formed.

In the meantime, the above-described effect of forming the aluminum-containing film is not obtained by only the combination between the aluminum and silicon oxide, and it is indicated that the energy band structure can be modulated by forming another oxide at the interface of different kinds of oxides. For example, by forming a very thin aluminum-containing film (barrier film 21) at the interface between the silicon oxide film (gate insulation film 12) and hafnium oxide (ferroelectric film 13), the insulation characteristics of the multilayer insulation film greatly change. When electrons are injected from the silicon oxide film side, leak current is reduced by forming the aluminum-containing film. This indicates that the energy band can be modulated by forming the aluminum-containing film at the interface between different kinds of oxides.

As has been described above, according to the present embodiment, by forming the barrier film 21, which is formed of the aluminum-containing film, at the interface between the gate insulation film 12 and ferroelectric film 13, the energy band structure at this interface is modulated. Thus, the dielectric breakdown strength is enhanced, and leak current can be suppressed. Thereby, in order to enhance capabilities of transistors, the thickness of the gate insulation layer can be reduced, and device microfabrication can be achieved.

[2-3-2] Suppression of Silicon Diffusion

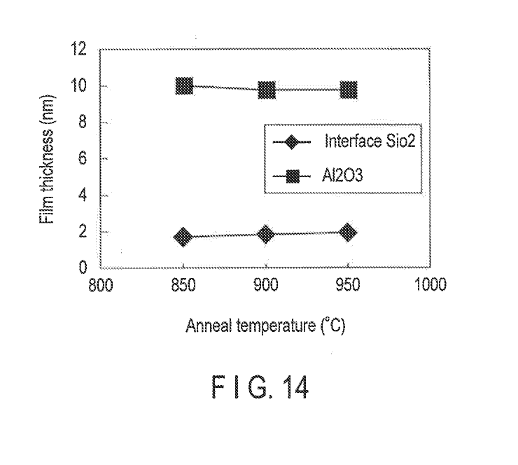

Referring to FIG. 14, suppression of silicon diffusion is explained.

FIG. 14 shows the dependency on heat treatment temperatures of a film thickness of an alumina film (Al₂O₃ film) and a film thickness of a silicon oxide film (SiO₂ film) in a case of heat treatment in a nitrogen atmosphere. The heat treatment temperature is in a range of between 850° C. and 950° C. In a sample used in this example, a silicon oxide film and an alumina film are formed on a silicon substrate.

As shown in FIG. 14, even if the heat treatment temperature is raised, the film thickness of the silicon oxide film does not vary. In short, no decrease occurs in film thickness of the silicon oxide film due to diffusion of silicon in the silicon oxide film into alumina. This results from the fact that alumina suppresses diffusion of silicon.

As has been described above, according to the present embodiment, with the provision of the barrier film 21 that is formed of the aluminum-containing film, it is possible to suppress diffusion of silicon in the gate insulation film 12, which is formed of the silicon oxide film, into the ferroelectric film 13. Thus, since it is possible to suppress an increase in Si concentration in the ferroelectric film 13 on the gate insulation film 12 side, degradation in ferroelectricity at the interface can be suppressed.

[2-4] Modifications

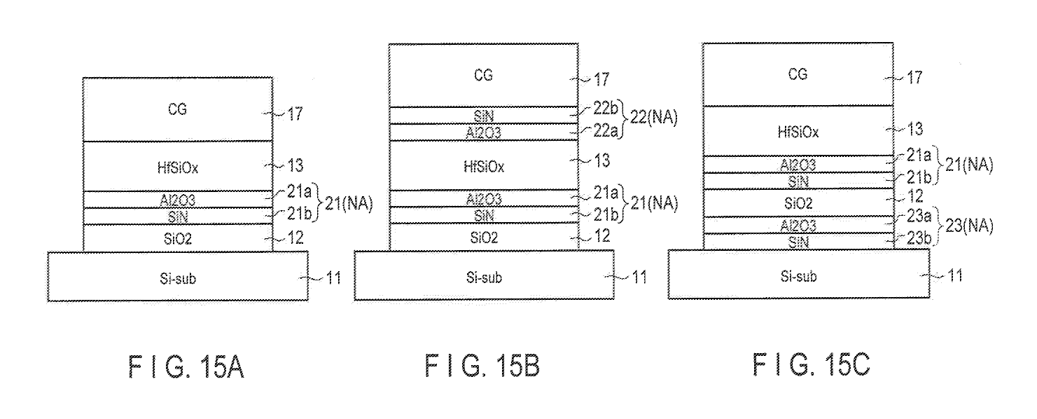

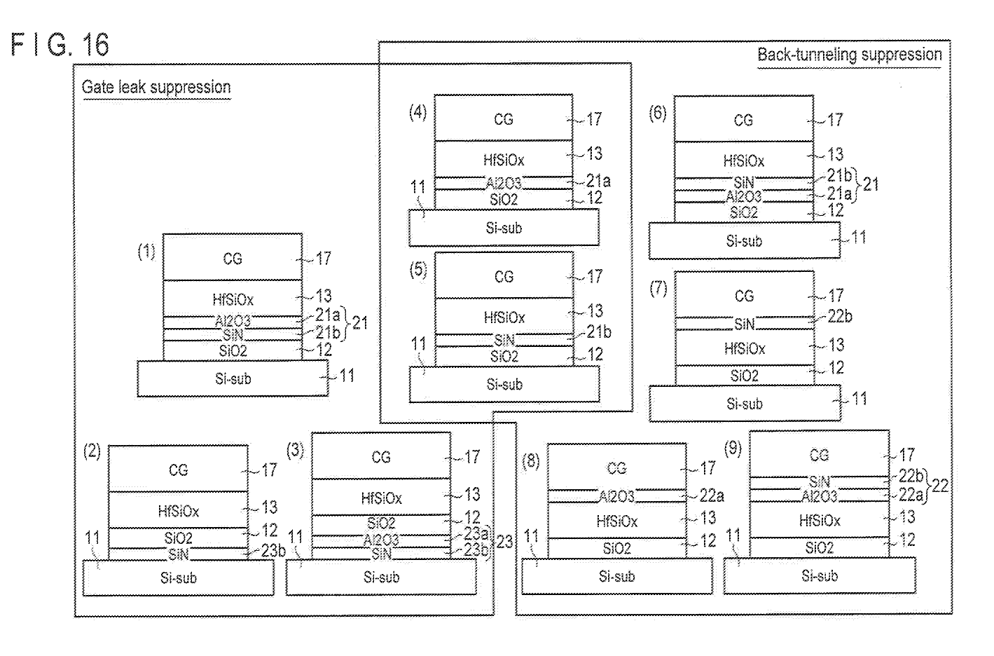

Using FIGS. 15A, 15B, and 15C, and FIG. 16, modifications of the ferroelectric memory according to the second embodiment are described.

As shown in FIG. 15A, the barrier film 21 of the present embodiment is not limited to a single layer, and may be a multilayer. Specifically, a barrier layer 21 of an NA structure, in which an Al₂O₃ film 21a and an SiN film 21b are stacked, may be formed between the gate insulation film 12 and ferroelectric film 13. In the case of the NA structure shown in FIG. 15A, it is possible to suppress injection of elections from the silicon substrate 11. In the meantime, in the case of an AN structure in which the order of stacking of the Al₂O₃ film 21a and SiN film 21b constituting the barrier film 21 is reversed, it is possible to suppress injection of elections from the control electrode 17. In addition, in the case where the barrier layer 21 has an NAN structure comprising three layers of SiN film/Al₂O film/SiN film, it is possible to suppress both injection of electrons from the silicon substrate 11 and injection of electrons from the control electrode 17.

As shown in FIG. 15B, the barrier film 21 of the embodiment is not limited to the case in which the barrier film 21 is formed only between the gate insulation film 12 and ferroelectric film 13, and a barrier film 22 may be also formed between the ferroelectric film 13 and control gate 17. Specifically, a barrier layer 21 of an NA structure, in which an SiN film 21b and an Al₂O₃ film 21a are stacked, may be formed between the gate insulation film 12 and ferroelectric film 13, and a barrier layer 22 of an AN structure, in which an Al₂O₃ film 22a and an SiN film 22b are stacked, may be formed between the ferroelectric film 13 and control gate 17. In the case of the structure shown in FIG. 15B, electron injection from the silicon substrate 11 can be suppressed by the barrier film 21 at the interface of the ferroelectric film 13/gate insulation film 12, and electron injection from the control electrode 17 can be suppressed by the barrier film 22 at the interface of the ferroelectric film 13/control electrode 17. In the meantime, in the barrier film 21 including the SiN film 21b/Al₂O₃ film 21a, the SiN film 21b is disposed on the silicon substrate 11 side when electron injection from the silicon substrate 11 is suppressed. In the barrier film 22 including the Al₂O₃ film 22a/SiN film 22b, the SiN film 22b is disposed on the control electrode 17 side when electron injection from the control electrode 17 is suppressed.

As shown in FIG. 15C, the barrier film 21 of the embodiment is not limited to the case in which the barrier film 21 is formed only between the gate insulation film 12 and ferroelectric film 13, and a barrier film 23 may be also formed between the silicon substrate 11 and gate insulation film 12. Specifically, a barrier layer 21 of an NA structure, in which an SiN film 21b and an Al₂O₃ film 21a are stacked, may be formed between the gate insulation film 12 and ferroelectric film 13, and a barrier layer 23 of an NA structure, in which an Al₂O₃ film 23a and an SiN film 23b are stacked, may be formed between the silicon substrate 11 and gate insulation film 12. In the case of the structure shown in FIG. 15C, by additionally forming the barrier layer 23 of the NA structure at the interface of the silicon substrate 11/gate insulation film 12, electron injection from the silicon substrate 11 can further be suppressed.

The film structures and the positions of formation in FIGS. 15A, 15B, and 15C may be combined in any possible variation. For example, as shown in FIG. 16, structures (1) to (5) have high effects of suppression of gate leak current, and structures (4) to (9) have high effects of back-tunneling suppression. In this manner, the barrier film of the present embodiment can be variously modified according to effects that are required.

### [3] Third Embodiment

In a third embodiment, prior to heat treatment for orthorhombic crystallization, impurities are ion-implanted in an amorphous metal oxide film, whereby the metal oxide film is uniformly orthorhombically crystallized.

[3-1] Manufacturing Method

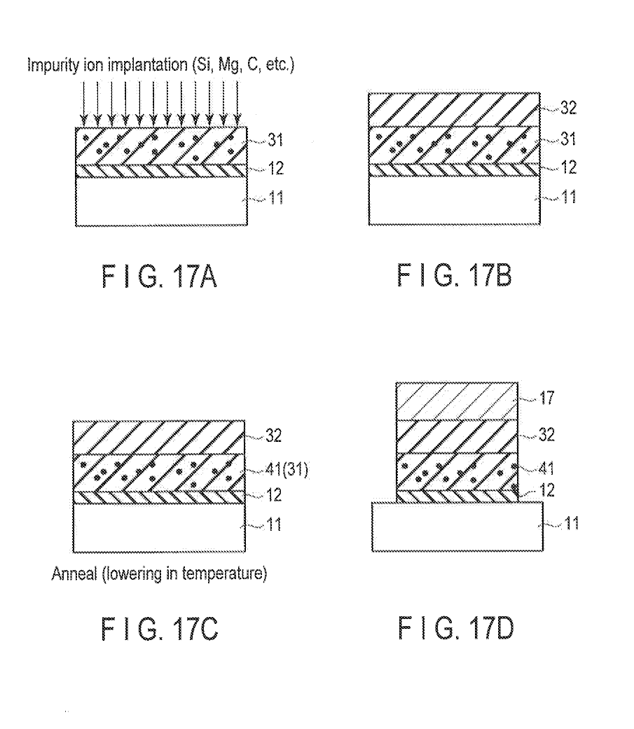

Referring to FIGS. 17A, 17B, 17C, and 17D, a description is given of a manufacturing method of a ferroelectric memory according to the third embodiment.

To start with, as shown in FIG. 17A, a gate insulation film 12, which is made of a silicon oxide film, is formed on a silicon substrate 11. A metal oxide film 31, which is made of, e.g. an amorphous HfSiO film, is formed on the gate insulation film 12 by an ALD method. Thereafter, impurities are ion-implanted in the metal oxide film 31.

Next, as shown in FIG. 17B, a tensile stress film 32 is formed on the metal oxide film 31. The tensile stress film 32 has such a tensile stress as to apply a compression stress to the metal oxide film 31. As the tensile stress film 32, for example, use may be made of TiN, SiN, etc. which is formed by CVD, or TiN, TaN, W, etc. which is formed by PVD.

Subsequently, as shown in FIG. 17C, heat treatment of the substrate is performed while a film stress by the tensile stress film 32 is being applied to the metal oxide film 31. Thereby, the metal oxide film 31 is orthorhombically crystallized, and a metal oxide film (ferroelectric film) 41 having uniform ferroelectricity over the entire substrate surface is formed.

Next, as shown in FIG. 17D, a control electrode 17 is formed on the metal oxide film 41, and the control electrode 17 is patterned by exposure drawing. Thereafter, the ferroelectric memory is completed through an ordinary post-step.

As the impurities which are ion-implanted as illustrated in FIG. 17A, for example, inert gas, such as He, Ar, Xe or Kr, may be used. Such inert gas does not form a compound with an element which constitutes the metal oxide film 31, and has a pressurizing effect for compressing the metal oxide film 31 by thermal expansion in subsequent heat treatment, and thus orthorhombic crystallization becomes easy to occur at lower temperatures. In addition, since such inert gas is ultimately desorbed from the metal oxide film 31 by heat treatment, a vacancy occurs after the desorption. Migration of atoms via the vacancy is promoted, and crystallization is facilitated. As a result, heat treatment temperatures can be lowered.

In addition, as the impurities to be ion-implanted, for example, Si, Mg, C, Al, Y, etc. may be used. In this case, crystal nuclei in the HfSiO film 31 can be broken, and orthorhombic crystallization becomes easy to occur by subsequent heat treatment by doping Si, Mg, C, Al, Y, etc. with a desired concentration (e.g. 0.02 or more and 0.05 or less).

In the present embodiment, prior to forming the tensile stress film 32, impurities are ion-implanted in the metal oxide film 31. Alternatively, after forming the tensile stress film 32, impurities may be ion-implanted in the metal oxide film 31. In this case, crystal nuclei, which were formed at a heating stage before forming the tensile stress film 32, can be broken by ion implantation, and uniform orthorhombic crystallization can be performed. In addition, if the crystallinity of the tensile stress film 32 is broken at the same time, growth of a crystal different from an orthorhombic crystal, whose crystal nucleus is the tensile stress film 32, can be suppressed.

[3-2] Structure

Referring to FIG. 17D, a description is given of the structure of the ferroelectric memory according to the third embodiment.

As shown in FIG. 17D, in the ferroelectric memory of the third embodiment, a gate insulation film 12 is formed on a silicon substrate 11, and a metal oxide film 41 having ferroelectricity is formed on the gate insulation film 12. A tensile stress film 32 is formed on the metal oxide film 41, and a control electrode 17 is formed on the tensile stress film 32.

The metal oxide film 41 is a film containing as main constituents a metal (e.g. hafnium (Hf), zirconium (Zr)) and oxygen, and contains an element (e.g. silicon (Si), magnesium (Mg), carbon (C), aluminum (Al), yttrium (Y)) other than the metal at a concentration (e.g. 0.02 or more and 0.05 or less) lower than the concentration of the metal. The metal oxide film 41 is formed of, for example, an HfSiOx film, a ZrSiOx film, an HfMgOx film, a ZrMgOx film, an HfCOx film, a ZrCOx film, etc.

[3-3] Advantageous Effects

In a conventional method of forming an orthorhombic HfSiO film having ferroelectricity, an amorphous HfSiO film is formed by an ALD method, and a stress film is formed on the amorphous HfSiO film, and then high-temperature heat treatment for orthorhombic crystallization of the HfSiO film is performed.

However, in this formation method, the amorphous HfSiO film immediately after the ALD includes crystal nuclei of a tetragonal crystal, a monoclinic crystal and a cubic crystal at levels which cannot be detected by X-ray diffraction. Thus, in the subsequent heat treatment with stress applied, it is highly possible that the vicinity of the crystal nucleus of the HfSiO film will be partly tetragonally crystallized, monoclinically crystallized or cubically crystallized, and will not become a desired orthorhombic crystal. In addition, by the heating of the substrate before forming the stress film, crystal nuclei of a tetragonal crystal, a monoclinic crystal and a cubic crystal at levels, which cannot be detected by X-ray diffraction, will form in the amorphous HfSiO film.

As described above, in the prior art, it is difficult to uniformly form an orthorhombic HfO2 film over the entire substrate surface at high temperatures under high pressure. In a part which cannot be orthorhombically crystallized, ferroelectric spontaneous polarization does not occur, and a memory function cannot be secured.

By contrast, in the third embodiment, after the amorphous metal oxide film 31 is formed, impurities are ion-implanted in the metal oxide film 31. Thereby, crystal nuclei of a tetragonal crystal, a monoclinic crystal and a cubic crystal existing in the amorphous metal oxide film 31 at levels, which cannot be detected by X-ray diffraction, are broken. Thus, in the subsequent heat treatment, the metal oxide film 31 can uniformly be orthorhombically crystallized. In addition, since there is no crystal nucleus other than orthorhombic crystals, orthorhombic crystallization can be made at low heat-treatment temperatures, for example, at 950° C. or less.

According to the third embodiment, the metal oxide film 41 having uniform ferroelectricity over the entire substrate surface can be formed at low temperatures, and it is possible to form at a high yield a ferroelectric memory including cells with improved cell characteristics, high capabilities and high integration density.

### [4] Fourth Embodiment

In a fourth embodiment, an amorphous metal oxide film is formed with impurities being doped, and a cap film which reacts with the doped impurities is formed on this metal oxide film, thereby uniformly orthorhombically crystallizing the metal oxide film,

[4-1] Manufacturing Method

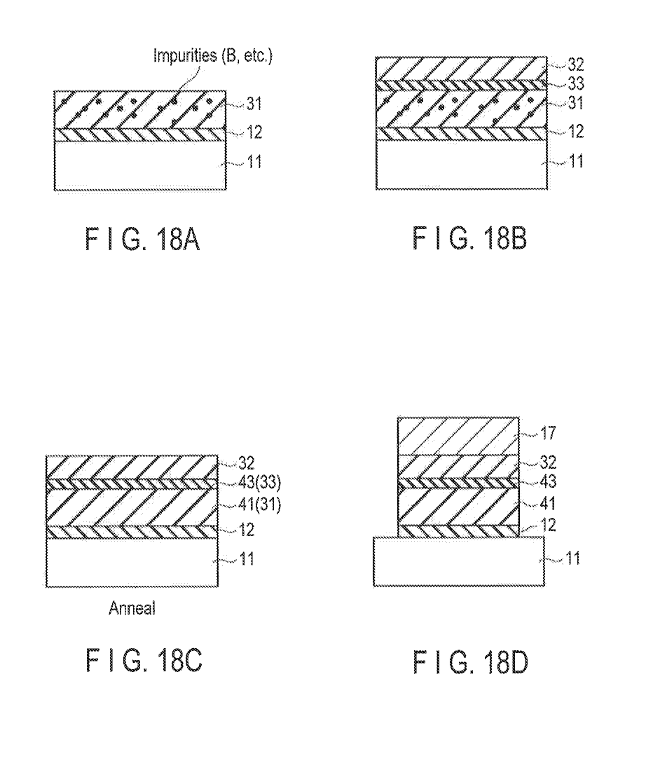

Referring to FIGS. 18A, 18B, 18C, and 18D, a description is given of a manufacturing method of a ferroelectric memory according to the fourth embodiment.

To start with, as shown in FIG. 18A, a gate insulation film 12, which is made of a silicon oxide film, is formed on a silicon substrate 11. Then, a metal oxide film 31, which is made of, e.g. an amorphous HfSiO film, is formed on the gate insulation film 12. At this time, the metal oxide film 31 is formed while an impurity element is being doped.

Next, as shown in FIG. 18B, a cap film 33 is formed on the metal oxide film 31, and a tensile stress film 32 is formed on the cap film 33. The cap film 33 is a film which reacts with impurities doped in the metal oxide film 31. The tensile stress film 32 has such a tensile stress as to apply a compression stress to the metal oxide film 31. As the tensile stress film 32, for example, use may be made of TiN, SiN, etc. which is formed by CVD, or TIN, TaN, W, etc. which is formed by PVD.

Subsequently, as shown in FIG. 18C, heat treatment of the substrate is performed. Thereby, a film stress by the tensile stress film 32 is applied to the metal oxide film 31, the metal oxide film 31 is orthorhombically crystallized, and a metal oxide film (ferroelectric film) 41 having uniform ferroelectricity over the entire substrate surface is formed. Furthermore, the impurities doped in the metal oxide film 31 are caused to react with the cap film 33, thereby forming a reaction film 43.

Next, as shown in FIG. 18D, a control electrode 17 is formed on the metal oxide film 41, and the control electrode 17 is patterned by exposure drawing. Thereafter, the ferroelectric memory is completed through an ordinary post-step.

As the impurities which are doped in the metal oxide film 31 as illustrated in FIG. 18A, for example, boron (B), carbon (C), etc. may be used.

In the case of using B as doped impurities, a film containing Ti, for example, is thinkable as the cap film 33 which reacts with B. B and Ti react easily, and TiB is easily formed as, the reaction film 43. Thus, by subsequent heat treatment, most of B in the metal oxide film 31 forms TiB at the upper interface. In addition, since B is an element with a small mass number, B diffuses easily in the metal oxide film 31, migration of atoms via a vacancy, where B diffuses, is promoted, and crystallization is facilitated. As a result, heat treatment temperatures can be lowered.

In the case of using C as doped impurities, a film containing Ti, Zr, etc., for example, is thinkable as the cap film 33 which reacts with C.

[4-2] Structure

Referring to FIG. 18D, a description is given of the structure of the ferroelectric memory according to the fourth embodiment.

As shown in FIG. 18D, in the ferroelectric memory of the fourth embodiment, a gate insulation film 12 is formed on a silicon substrate 11, and a metal oxide film 41 having ferroelectricity is formed on the gate insulation film 12. A reaction film 43 is formed on the metal oxide film 41, and a tensile stress film 32 is formed on the reaction film 43. A control electrode 17 is formed on the tensile stress film 32.

The metal oxide film 41 is a film containing as main constituents a metal (e.g. hafnium (Hf), zirconium (Zr)) and oxygen, and contains an element (e.g. silicon (Si), magnesium (Mg), aluminum (Al), yttrium (Y)) other than the metal at a concentration (e.g. 0.02 or more and 0.05 or less) lower than the concentration of the metal. The metal oxide film 41 is formed of, for example, an HfSiOx film, a ZrSiOx film, an HfMgOx film, a ZrMgOx film, etc.

Examples of the reaction film 43 include a film containing B and Ti (e.g. TiB), a film containing C and Ti (e.g. TIC), and a film containing C and Zr (e.g. ZrC).

In the meantime, doped impurities (e.g. B, C) for reaction with the cap film 33 may remain in the metal oxide film 41.

[4-3] Advantageous Effects

According to the fourth embodiment, like the third embodiment, the metal oxide film 41 having uniform ferroelectricity over the entire substrate surface can be formed at low temperatures, and it is possible to form at a high yield a ferroelectric memory including cells with improved cell characteristics, high capabilities and high integration density.

Specifically, in the fourth embodiment, the metal oxide film 31 is formed while impurities are being doped. Thus, a stable crystal structure becomes difficult to form. Thereby, the amorphous metal oxide film 31, which includes a less number of crystal nuclei of a tetragonal crystal, a monoclinic crystal and a cubic crystal at levels which cannot be detected by X-ray diffraction, can be formed. In addition, doped impurities in the metal oxide film 31 diffuse into the cap film 33, and a vacancy occurs in the metal oxide film 31. Migration of atoms via the vacancy is promoted, and crystallization is facilitated. As a result, in the subsequent heat treatment, the metal oxide film 31 can uniformly be orthorhombically crystallized. In addition, since there is no crystal nucleus other than orthorhombic crystals, orthorhombic crystallization can be made at low heat-treatment temperatures, for example, at 950° C. or less.

### [5] Fifth Embodiment

In a fifth embodiment, a crystallization seed film having a crystal, which is lattice-matched with an orthorhombic metal oxide film, is formed, whereby the metal oxide film is uniformly orthorhombically crystallized.

[5-1] Manufacturing Method

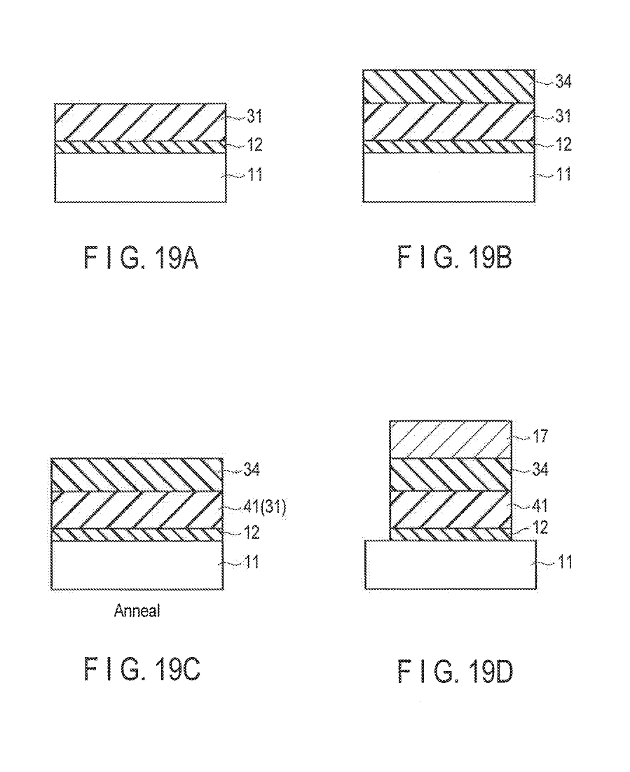

Referring to FIGS. 19A, 19B, 19C, and 19D, a description is given of a manufacturing method of a ferroelectric memory according to the fifth embodiment.

To start with, as shown in FIG. 19A, a gate insulation film 12, which is made of a silicon oxide film, is formed on a silicon substrate 11. A metal oxide film 31, which is made of, e.g. an amorphous HfSiO film, is formed on the gate insulation film 12 by an ALD method.

Next, a crystallization seed film 34 is formed on the metal oxide film 31. This crystallization seed film 34 is a film having a crystal, which is lattice-matched with an orthorhombic metal oxide film 41, and is formed of, for example, ZrO₂, TiO₂, etc. For example, it is desirable that a difference between a lattice constant a of the orthorhombic metal oxide film 41 and a lattice constant b of the crystallization seed film 34 be, for example, less than 5%.

Subsequently, as shown in FIG. 19C, heat treatment of the substrate is performed. Thereby, by crystal transmission of the crystallization seed film 34, crystallization of the metal oxide film 31 progresses, and an orthorhombic metal oxide film (ferroelectric film) 41 having uniform ferroelectricity over the entire substrate surface is formed.

Next, as shown in FIG. 19D, a control electrode 17 is formed on the metal oxide film 41, and the control electrode 17 is patterned by exposure drawing. Thereafter, the ferroelectric memory is completed through an ordinary post-step.

[5-2] Structure

Referring to FIG. 19D, a description is given of the structure of the ferroelectric memory according to the fifth embodiment.

As shown in FIG. 19D, in the ferroelectric memory of the fifth embodiment, a gate insulation film 12 is formed on a silicon substrate 11, and a metal oxide film 41 having ferroelectricity is formed on the gate insulation film 12. A crystallization seed film 34 is formed on the metal oxide film 41, and a control electrode 17 is formed on the crystallization seed film 34.

The metal oxide film 41 is a film containing as main constituents a metal (e.g. hafnium (Hf), zirconium (Zr)) and oxygen, and contains an element (e.g. silicon (Si), magnesium (Mg), aluminum (Al), yttrium (Y)) other than the metal at a concentration (e.g. 0.02 or more and 0.05 or less) lower than the concentration of the metal. The metal oxide film 41 is formed of, for example, an HfSiOx film, a ZrSiOx film, an HfMgOx film, a ZrMgOx film, etc.

The crystallization seed film 34 includes a crystal which is lattice-matched with the orthorhombic metal oxide film 41, and is, for example, ZrO₂, TiO₂, etc.

[5-3] Advantageous Effects

According to the fifth embodiment, like the third embodiment, the metal oxide film 41 having uniform ferroelectricity over the entire substrate surface can be formed at low temperatures, and it is possible to form at a high yield a ferroelectric memory including cells with improved cell characteristics, high capabilities and high integration density.

Specifically, in the fifth embodiment, after the crystallization seed film 34, which has a crystal that is lattice-matched with the orthorhombic metal oxide film 41, is formed on the amorphous metal oxide film 31, heat treatment for orthorhombic crystallization is performed. Thus, in this heat treatment, crystallization of the metal oxide film 31 progresses from the upper film, and the metal oxide film 31 can uniformly be orthorhombically crystallized. In addition, since there is no crystal nucleus other than orthorhombic crystals, orthorhombic crystallization can be made at low heat-treatment temperatures, for example, at 950° C. or less.

### [6] Sixth Embodiment

In a sixth embodiment, in a BiCS structure, a thermal expansion film is buried in a memory hole, and compression stress is applied to a metal oxide film by the thermal expansion film in heat treatment for orthorhombic crystallization, thereby uniformly orthorhombically crystallizing the metal oxide film.

[6-1] Manufacturing Method

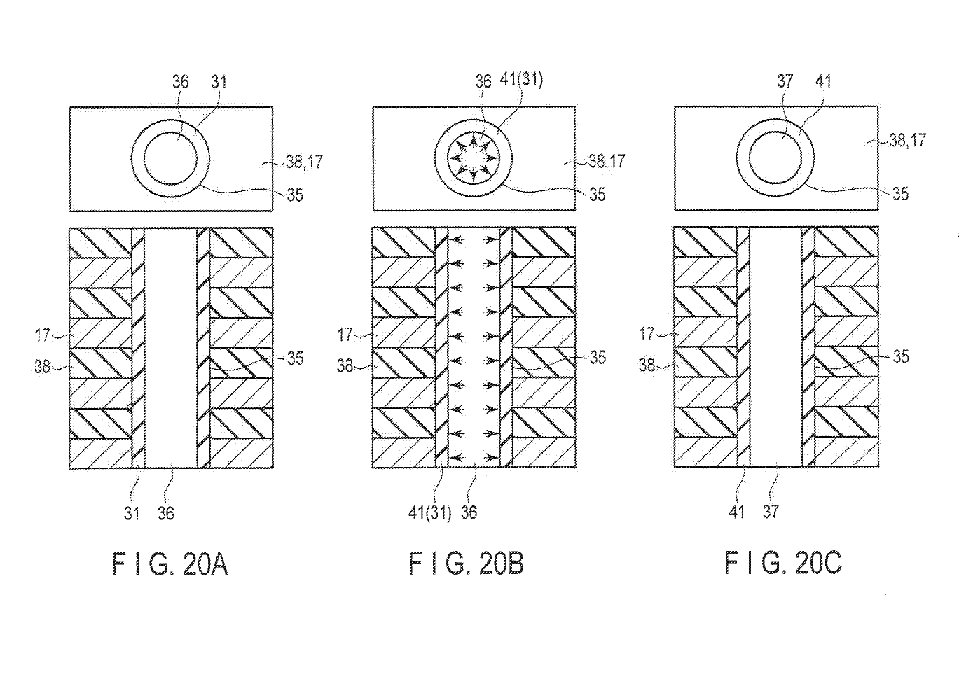

Referring to FIGS. 20A, 20B, and 20C, a description is given of a manufacturing method of a ferroelectric memory with a BiCS structure according to the sixth embodiment.

To start with, as shown in FIG. 20A, a control electrode 17 and an interlayer insulation film 38 are alternately stacked, thereby constituting a multilayer stack structure. Then, by a dry etching method, a memory hole 35 penetrating the multilayer stack structure is formed. A metal oxide film 31, which is made of an amorphous HfSiO film, is formed on the inner wall of the memory hole 35. Further, the inside of the memory hole 35 is filled with a thermal expansion film 36 which extends in volume by heat. The thermal expansion film 36 should preferably be formed of a material with a higher linear expansion coefficient than Si (linear expansion coefficient=0.5e-6/K) or SiO₂ (2.6), for instance, a Si-rich SiO₂ film, Ge (5.7), AlN (5.7), Al₂O₃ (8.4), TiO₉ (9), VN (9.2), TiN (9.4), NbN (10), ZrO₂ (11), MgO (13), etc.

Subsequently, as shown in FIG. 20B, heat treatment is performed, whereby the thermal expansion film 36 expands in volume, applies compression stress to the metal oxide film 31, and orthorhombically crystallizing the metal oxide film 31. Thereby, a metal oxide film (ferroelectric film) 41 having uniform ferroelectricity over the entire substrate surface is formed.

Next, as shown in FIG. 20C, after the thermal expansion film 36 is removed, a gate insulation film (not shown) and a channel layer 37 are formed. Thereafter, the ferroelectric memory is completed through an ordinary post-step.

[6-2] Structure

Referring to FIG. 20C, a description is given of a BiCS structure of the ferroelectric memory according to the sixth embodiment.

As illustrated in FIG. 20C, in the ferroelectric memory of the sixth embodiment, a control electrode 17 and an interlayer insulation film 38 are alternately stacked, and a memory hole 35 penetrating the stack structure is provided. A gate insulation film (not shown) and a metal oxide film 41 are stacked on the inner wall of the memory hole 35, and a channel layer 37 is buried in the central part of the memory hole 35.

The metal oxide film 41 is a film containing as main constituents a metal (e.g. hafnium (Hf), zirconium (Zr)) and oxygen, and contains an element (e.g. silicon (Si), magnesium (Mg), aluminum (Al), yttrium (Y)) other than the metal at a concentration (e.g. 0.02 or more and 0.05 or less) lower than the concentration of the metal. The metal oxide film 41 is formed of, for example, an HfSiOx film, a ZrSiOx film, an HfMgOx film, a ZrMgOx film, etc.

[6-3] Advantageous Effects

According to the sixth embodiment, like the third embodiment, the metal oxide film 41 having uniform ferroelectricity over the entire substrate surface can be formed at low temperatures, and it is possible to form at a high yield a ferroelectric memory including cells with improved cell characteristics, high capabilities and high integration density.

Specifically, in the sixth embodiment, after the thermal expansion film 36 is buried in the memory hole 35, heat treatment for orthorhombic crystallization is performed. Thus, in this heat treatment, since the volume of the thermal expansion film 36 expands and compression stress is applied to the metal oxide film 31, the metal oxide film 31 can uniformly be orthorhombically crystallized. In addition, since there is no crystal nucleus other than orthorhombic crystals, orthorhombic crystallization can be made at low heat-treatment temperatures, for example, at 950° C. or less.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A ferroelectric memory comprising:
a gate insulation film formed on a semiconductor substrate;
a ferroelectric film formed on the gate insulation film; and
a control electrode formed on the ferroelectric film,
wherein the ferroelectric film contains a metal, which is hafnium or zirconium, and oxygen, and contains an element other than the metal at a concentration lower than a concentration of the metal, and
the concentration of the element other than the metal is non-uniform in a film thickness direction of the ferroelectric film.

2. The memory of claim 1, wherein the element other than the metal is silicon, magnesium, aluminum or yttrium.

3. The memory of claim 2, wherein a concentration of the silicon, the magnesium, the aluminum or the yttrium is low at an interface between the ferroelectric film and the gate insulation film.

4. The memory of claim 2, wherein a concentration of the silicon, the magnesium, the aluminum or the yttrium is high at an interface between the ferroelectric film and the gate insulation film.

5. The memory of claim 2, wherein a concentration of the silicon, the magnesium, the aluminum or the yttrium is high at an interface between the ferroelectric film and the control electrode.

6. The memory of claim 2, wherein a concentration of the silicon, the magnesium, the aluminum or the yttrium is higher at an interface between the ferroelectric film and the gate insulation film and at an interface between the ferroelectric film and the control electrode than at a central part of the ferroelectric film.

7. The memory of claim 2, wherein an atomicity of the element other than the metal/(the atomicity of the element other than the metal+an atomicity of the metal) is in a range of between 0.02 and 0.05 at the interface between the ferroelectric film and the gate insulation film.

8. The memory of claim 2, wherein an atomicity of the element other than the metal/(the atomicity of the element other than the metal+an atomicity of the metal) is in a range of between 0.026 and 0.034 at the interface between the ferroelectric film and the gate insulation film.

9. A ferroelectric memory comprising:
a gate insulation film formed on a semiconductor substrate;
a ferroelectric film formed on the gate insulation film; and
a control electrode formed on the ferroelectric film,
wherein the ferroelectric film contains a metal, which is hafnium or zirconium, and oxygen, and contains an element other than the metal at a concentration lower than a concentration of the metal,
the element other than the metal is nitrogen, and
a concentration of the nitrogen in the ferroelectric film is uniform or non-uniform in, a film thickness direction of the ferroelectric film.

10. The memory of claim 9, wherein in a case where the concentration of the nitrogen is non-uniform in the film thickness direction of the ferroelectric film, the concentration of the nitrogen is high at least at one of an interface between the gate insulation film and the ferroelectric film and an interface between the control electrode and the ferroelectric film.

11. A ferroelectric memory comprising:
a gate insulation film formed on a semiconductor substrate;
a barrier film formed on the gate insulation film;
a ferroelectric film formed on the barrier film; and
a control electrode formed on the ferroelectric film,
wherein the ferroelectric film is a film containing a metal, which is hafnium or zirconium, and oxygen, and an atomicity of an element other than the metal/(the atomicity of the element other than the metal+an atomicity of the metal) is in a range of between 0.02 and 0.05.

12. The memory of claim 11, wherein the element other than the metal is silicon, magnesium, aluminum or yttrium.

13. The memory of claim 11, wherein the barrier film is formed of at least one of an aluminum-containing film and a silicon nitride film.

14. The memory of claim 13, wherein a concentration of aluminum in the aluminum-containing film is in a range of between 1e12 atoms/cm⁻² and 1e16 atoms/cm⁻².

15. The memory of claim 11, wherein the barrier film is formed of at least one of a lanthanum containing film and a silicon nitride film.

16. A ferroelectric memory comprising:
a gate insulation film formed on a semiconductor substrate;
a metal oxide film formed on the gate insulation film;
a tensile stress film formed on the metal oxide film; and
a control electrode formed on the tensile stress film,
wherein the metal oxide film is a film containing a metal, which is hafnium or zirconium, and oxygen, and an atomicity of an element other than the metal/(the atomicity of the element other than the metal+an atomicity of the metal) is in a range of between 0.02 and 0.05, and
the element other than the metal is silicon, magnesium, carbon, aluminum or yttrium.

17. A ferroelectric memory comprising:
a gate insulation film formed on a semiconductor substrate;
a metal oxide film formed on the gate insulation film;
a reaction film formed on the metal oxide film;
a tensile stress film formed on the reaction film; and
a control electrode formed on the tensile stress film,
wherein the metal oxide film is a film containing a metal, which is hafnium or zirconium, and oxygen, and
the reaction film is a film containing B and Ti, a film containing C and Ti, or a film containing C and Ar.

18. A ferroelectric memory comprising:
a gate insulation film formed on a semiconductor substrate;
a metal oxide film formed on the gate insulation film;
a crystallization seed film formed on the metal oxide film; and
a control electrode formed on the crystallization seed film,
wherein the metal oxide film is a film containing a metal, which is hafnium or zirconium, and oxygen, and
the crystallization seed film includes a crystal which is lattice-matched with the metal oxide film.
